(19) United States
(12) Patent Application Publication
(10) Pub. No.: US 2025/0149440 A1
(43) Pub. Date: May 8, 2025

(54) ELECTRONIC DEVICE AND METHOD FOR MANUFACTURING THE SAME

(71) Applicant: United Microelectronics Corp., Hsinchu (TW)

(72) Inventors: Chien-Yi LEE, Hsinchu City (TW); Tse-Pu Chen, Hsinchu County (TW); Yi-Chin Li, Hualien County (TW); Sheng-Huei Dai, Taitung County (TW)

(21) Appl. No.: 18/393,771

(22) Filed: Dec. 22, 2023

(30) Foreign Application Priority Data
Nov. 3, 2023 (TW) 112142517

(51) Int. Cl. H01L 23/522; H01L 29/94

(52) U.S. Cl. CPC H01L 23/5227; H10D 1/20; H10D 1/665

(57) ABSTRACT

An electronic device including a substrate with a trench and an inductor disposed on the substrate is provided. The inductor includes a first conductive layer and a second conductive layer. The first conductive layer is conformally disposed on the substrate. At least a portion of the first conductive layer is disposed in the trench. The first conductive layer has a first end portion and a second end portion. The second conductive layer is conformally disposed on the first conductive layer. The second conductive layer has a first end portion and a second end portion on the first end portion of the first conductive layer and the second end portion of the first conductive layer, respectively. The first end portion of the second conductive layer is electrically connected with the second end portion of the first conductive layer.

This application claims the benefit of Taiwan application Serial No. 112142517, filed on Nov. 3, 2023, the subject matter of which is incorporated herein by reference.

### TECHNICAL FIELD

This disclosure relates to an electronic device and a method for manufacturing the same. More particularly, the disclosure relates to an electronic device having a deep trench inductor (DTI) and a method for manufacturing the same.

### BACKGROUND

Electronic components, comprising resistors, capacitors, inductors, and so on, can be connected and combined in various ways to form a variety of electronic devices. In order to add capacitance to various integrated circuits, deep trench capacitors (DTCs) have been developed. A typical deep trench capacitor is formed by etching one or more deep trenches (DTs) into a substrate and then forming layers for the capacitor conformal to the deep trenches. In this manner, a “vertical” capacitor is formed. Such vertical deep trench electronic components can be more compact. In addition, deep trench electronic components can be freely placed as close as possible to the desired circuit. However, there are no other kinds of deep trench electronic components other than the deep trench capacitors to this day.

### SUMMARY

In this disclosure, an inductor that can be incorporated with a deep trench structure and various implementations related thereto are provided.

In one aspect of the disclosure, an electronic device is provided. The electronic device comprises a substrate and an inductor. The substrate has a trench. The inductor is disposed on the substrate. The inductor comprises a first conductive layer and a second conductive layer. The first conductive layer is conformally disposed on the substrate. At least a portion of the first conductive layer is disposed in the trench. The first conductive layer has a first end portion and a second end portion. The second conductive layer is conformally disposed on the first conductive layer. The second conductive layer has a first end portion and a second end portion on the first end portion of the first conductive layer and the second end portion of the first conductive layer, respectively. The first end portion of the second conductive layer is electrically connected with the second end portion of the first conductive layer.

In another aspect of the disclosure, a method for manufacturing an electronic device is provided. The method comprises following steps. First, a substrate is provided. The substrate has a trench. Then, a first conductive layer is conformally formed on the substrate. At least a portion of the first conductive layer is formed in the trench. The first conductive layer has a first end portion and a second end portion. A second conductive layer is conformally formed on the first conductive layer. The second conductive layer has a first end portion and a second end portion on the first end portion of the first conductive layer and the second end portion of the first conductive layer, respectively. Thereafter, the first end portion of the second conductive layer and the second end portion of the first conductive layer are electrically connected.

The inductor according to the disclosure can be used together with any suitable electronic components, and particular a deep trench capacitor. The manufacturing process of the inductor is compatible with the manufacturing process of the deep trench capacitor.

### BRIEF DESCRIPTION OF THE DRAWINGS

FIG. 1A-1C illustrate an exemplary electronic device according to the disclosure.

FIG. 2 is a flow chart of a method for manufacturing an electronic device according to the disclosure.

FIGS. 3A-3H illustrate various stage of an exemplary method for manufacturing an electronic device according to the disclosure.

FIGS. 4A-4B illustrate another exemplary electronic device according to the disclosure.

FIGS. 5A-5B illustrate still another exemplary electronic device according to the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

In the disclosure, a kind of electronic device is provided. An electronic device of this kind comprises a substrate and an inductor. The substrate has a trench. The inductor is disposed on the substrate. The inductor comprises a first conductive layer and a second conductive layer. The first conductive layer is conformally disposed on the substrate. At least a portion of the first conductive layer is disposed in the trench. The first conductive layer has a first end portion and a second end portion. The second conductive layer is conformally disposed on the first conductive layer. The second conductive layer has a first end portion and a second end portion on the first end portion of the first conductive layer and the second end portion of the first conductive layer, respectively. The first end portion of the second conductive layer is electrically connected with the second end portion of the first conductive layer.

The first conductive layer and the second conductive layer can be isolated from each other with a suitable means. For example, the inductor can further comprise a first dielectric layer conformally disposed on the first conductive layer, and the second conductive layer is conformally disposed on the first dielectric layer. As such, the first conductive layer and the second conductive layer can be isolated by the first dielectric layer.

In some embodiments, the first end portion of the first conductive layer and the first end portion of the second conductive layer can form a stair structure, and the second end portion of the first conductive layer and the second end portion of the second conductive layer can form a stair structure. Such a structure is beneficial for the formation of an electrical connection structure between the first end portion of the second conductive layer and the second end portion of the first conductive layer. For example, the inductor can further comprise an overlying conductive portion and conductive connectors. The overlying conductive portion is disposed over the second conductive layer. The conductive connectors are connected between the overlying conductive portion and the first end portion of the second conductive layer and between the overlying conductive portion and the second end portion of the first conductive layer. As such, a “vertical” electrical connection structure can be formed between the first end portion of the second conductive layer and the second end portion of the first conductive layer, and thus a “vertical” inductor e can be formed. However, it can be understood that a vertical electrical connection structure may not be used or not be fully used as long as the directions of magnetic field lines are not affected too much to fail the inductor.

In the disclosure, “loops” of the inductor are defined based on the number of the conductive layers that are conformal with the trench. The inductor according to the disclosure may be an inductor having the simplest structure with two loops as defined above (i.e., a two-loops inductor), or an inductor having three loops, four loops, or even more loops.

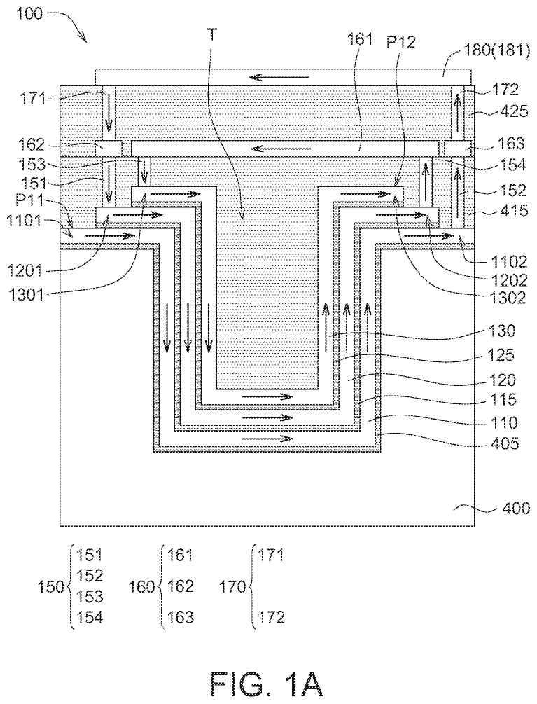

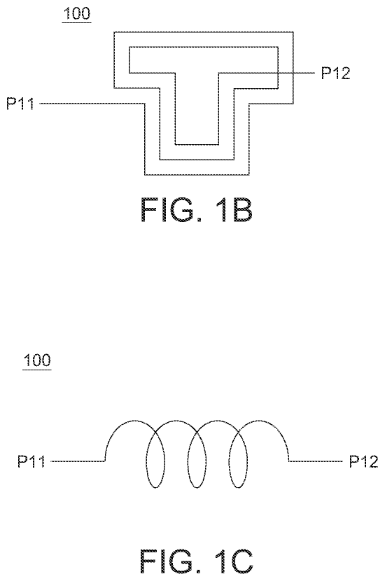

FIG. 1A-1C illustrate an exemplary electronic device according to the disclosure comprising an inductor 100 having three loops (i.e., a three-loops inductor), wherein FIG. 1A shows a specific structure of the inductor 100, FIG. 1B shows a simplified structure in which only the components involved in the current flow are shown and represented by lines, and FIG. 1C is a circuit diagram of the inductor 100.

Referring to FIG. 1A, a substrate 400 of the electronic device is also shown in FIG. 1A. The substrate 400 has a trench T for the formation of the inductor 100. The electronic device can comprise a liner layer 405 firstly formed on the substrate 400 for isolation between the inductor 100 and the substrate 400. The liner layer 405 can be formed of oxide.

The inductor 100 is disposed on the substrate 400 with a portion thereof disposed in the trench T. The inductor 100 comprises a first conductive layer 110, a first dielectric layer 115, a second conductive layer 120, a second dielectric layer 125, and a third conductive layer 130 disposed sequentially.

The first conductive layer 110 is conformally disposed on the substrate 400. At least a portion of the first conductive layer 110 is disposed in the trench T. The first conductive layer 110 has a first end portion 1101 and a second end portion 1102. The first conductive layer 110 can be formed of Cu, Al, or TiN.

The first dielectric layer 115 is conformally disposed on the first conductive layer 110. The first dielectric layer 115 can be formed of a high-k material.

The second conductive layer 120 is conformally disposed on the first conductive layer 110. More specifically, the second conductive layer 120 is conformally disposed on the first dielectric layer 115 positioned on the first conductive layer 110. The second conductive layer 120 has a first end portion 1201 and a second end portion 1202 on the first end portion 1101 of the first conductive layer 110 and the second end portion 1102 of the first conductive layer 110, respectively. The first end portion 1201 of the second conductive layer 120 is electrically connected with the second end portion 1102 of the first conductive layer 110. The second conductive layer 120 can be formed of Cu, Al, or TiN.

The second dielectric layer 125 is conformally disposed on the second conductive layer 120. The second dielectric layer 125 can be formed of a high-k material.

The third conductive layer 130 is conformally disposed on the second conductive layer 120. More specifically, the third conductive layer 130 is conformally disposed on the second dielectric layer 125. The third conductive layer 130 has a first end portion 1301 and a second end portion 1302 on the first end portion 1201 of the second conductive layer 120 and the second end portion 1202 of the second conductive layer 120, respectively. The first end portion 1301 of the third conductive layer 130 is electrically connected with the second end portion 1202 of the second conductive layer 120. The third conductive layer 130 can be formed of Cu, Al, or TiN.

The first end portion 1301 of the third conductive layer 130 together with the first end portion 1101 of the first conductive layer 110 and the first end portion 1201 of the second conductive layer 120 can form a stair structure, and the second end portion 1302 of the third conductive layer 130 together with the second end portion 1102 of the first conductive layer 110 and the second end portion 1202 of the second conductive layer 120 can form a stair structure.

The inductor 100 can further comprise overlying conductive portions 161-163 and 181 and conductive connectors 150 and 170. Specifically, an interlayer dielectric layer 415 can be disposed on the substrate 400, and cover the first conductive layer 110, the first dielectric layer 115, the second conductive layer 120, the second dielectric layer 125, and the third conductive layer 130. The conductive connectors 150, comprising conductive connectors 151-154, can penetrate through the interlayer dielectric layer 415. A first overlying conductive layer 160, comprising the overlying conductive portions 161-163, can be disposed on the interlayer dielectric layer 415. An interlayer dielectric layer 425 can be disposed on the interlayer dielectric layer 415. The conductive connectors 170, comprising the conductive connectors 171-172, can penetrate through the interlayer dielectric layer 425. The second overlying conductive layer 180, comprising the overlying conductive portion 181, can be disposed on the interlayer dielectric layer 425.

The overlying conductive portions 161-163 and 181 are disposed over the second conductive layer 120. There are the conductive connectors 151-154 and 171-172, among which the conductive connectors 171 and 151 are connected between one of the overlying conductive portions 181 and the first end portion 1201 of the second conductive layer 120, the conductive connectors 172 and 152 are connected between the overlying conductive portion 181 and the second end portion 1102 of the first conductive layer 110, the conductive connector 153 is connected between another one of the overlying conductive portions 171 and the first end portion 1301 of the third conductive layer 130, and the conductive connector 154 is connected between the overlying conductive portion 171 and the second end portion 1202 of the second conductive layer 120. As such, adjacent conductive layers can be electrically connected such that the directions of currents therein are consistent, and thus the directions of magnetic field lines are consistent, so as to form a loop of the inductor. Herein, adjacent conductive layers refer to, among all the conductive layers that are conformal with the trench, the two conductive layers that do not have any other conductive layer therebetween, such as the first conductive layer 110 and the second conductive layer 120 as well as the second conductive layer 120 and the third conductive layer 130, regardless of whether there are other kinds of layers between the two conductive layers. It will be appreciated that the disclosure is not limited to the loop-constituting means as shown in FIG. 1A. For example, in FIG. 1A, the conductive connector 171 disposed in the interlayer dielectric layer 425 and the conductive connector 151 disposed in the interlayer dielectric layer 415 are connected through the overlying conductive portion 162, and the conductive connector 172 disposed in the interlayer dielectric layer 425 and the conductive connector 152 disposed in the interlayer dielectric layer 415 are connected through the overlying conductive portion 163. Instead, two conductive connectors directly penetrating through the interlayer dielectric layers 425 and 415 can be formed.

As such, a current path can be formed in the inductor 100 from a port P11 to a port P12, as indicated by arrows. FIG. 1B shows a simplified structure of the inductor 100 based on the current path. From FIG. 1B, it is easier to understand that while the inductor 100 has a certain thickness in the width direction of the trench T (i.e., the direction perpendicular to the paper surface), it can still be regarded as a planar inductor formed on a plane defined by an extending direction of the trench T and a normal direction of the substrate 400. This plane is perpendicular to is the substrate, so that the inductor 100 is a “vertical” inductor.

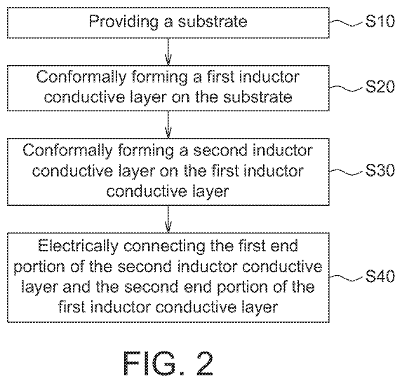

Referring to FIG. 2, a flow chart of a method for manufacturing an electronic device according to the disclosure is provided. In step S10, a substrate is provided. The substrate has a trench. In step S20, a first conductive layer is conformally formed on the substrate. At least a portion of the first conductive layer is formed in the trench. The first conductive layer has a first end portion and a second end portion. In step S30, a second conductive layer is conformally formed on the first conductive layer. The second conductive layer has a first end portion and a second end portion on the first end portion of the first conductive layer and the second end portion of the first conductive layer, respectively. In step S40, the first end portion of the second conductive layer and the second end portion of the first conductive layer are electrically connected.

In embodiments of manufacturing an electronic device with a two-loops inductor, electrically connecting the first end portion of the second conductive layer and the second end portion of the first conductive layer can simply comprise: forming two conductive connectors connected to the first end portion of the second conductive layer and connected to the second end portion of the first conductive layer, respectively; and forming an overlying conductive portion connecting the two conductive connectors.

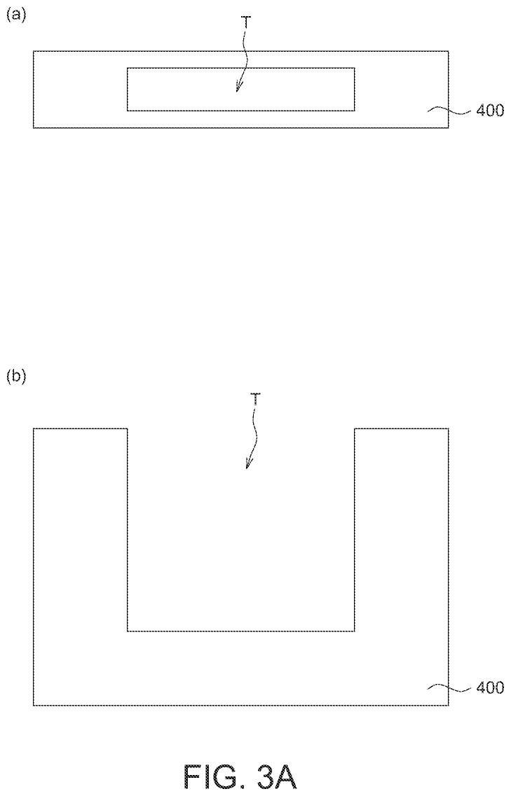

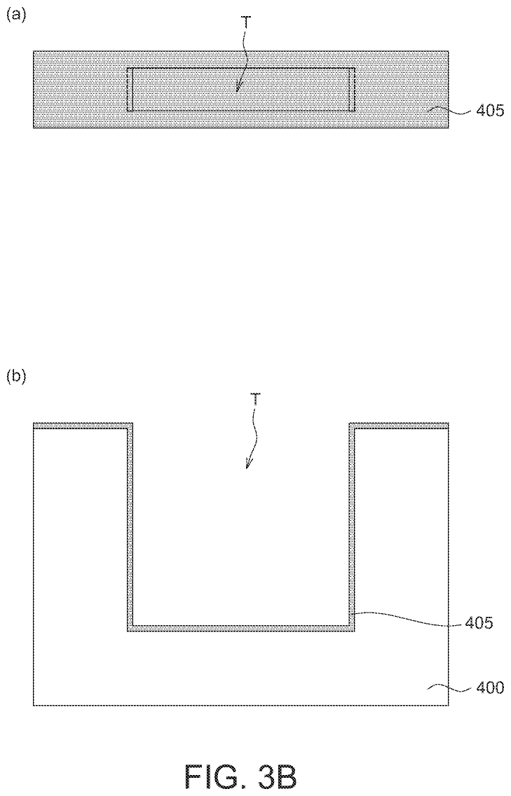

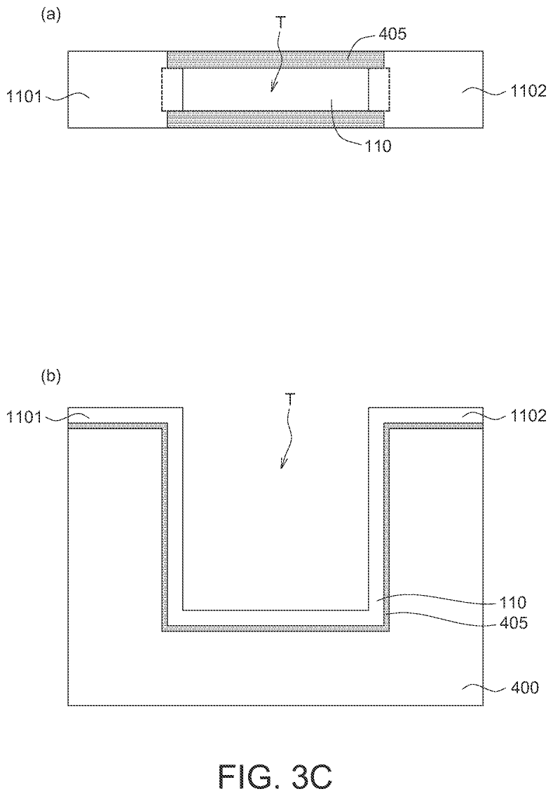

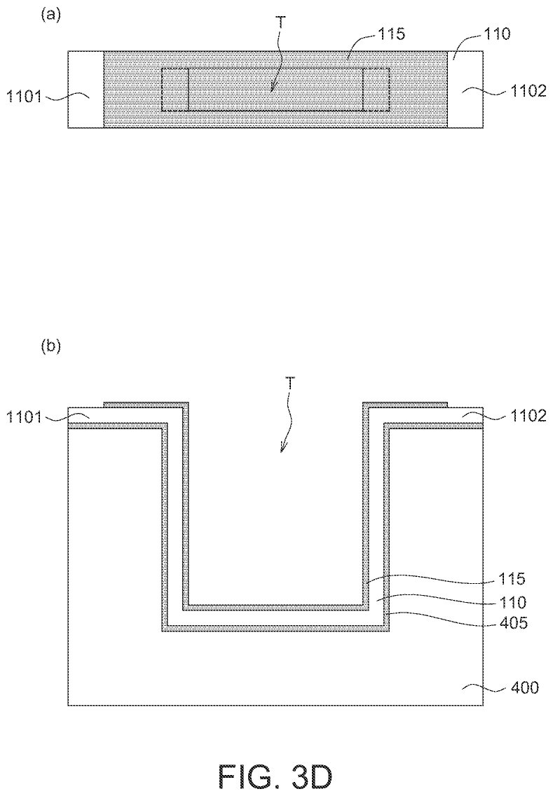

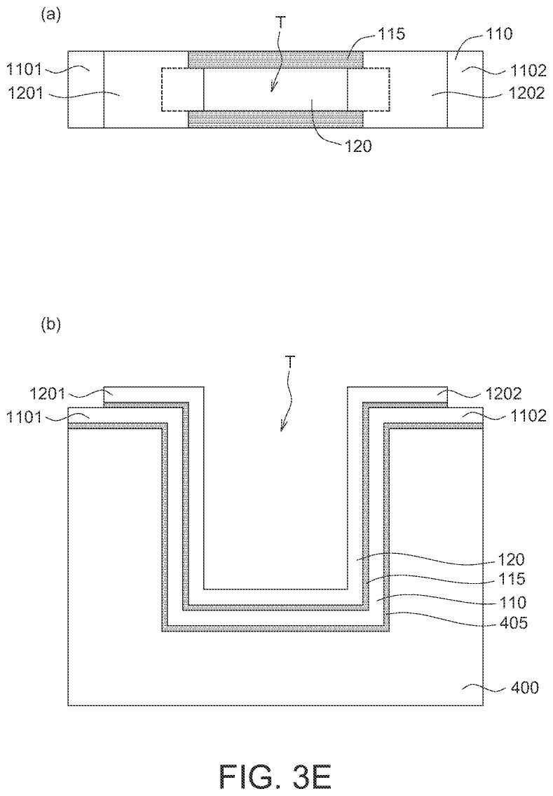

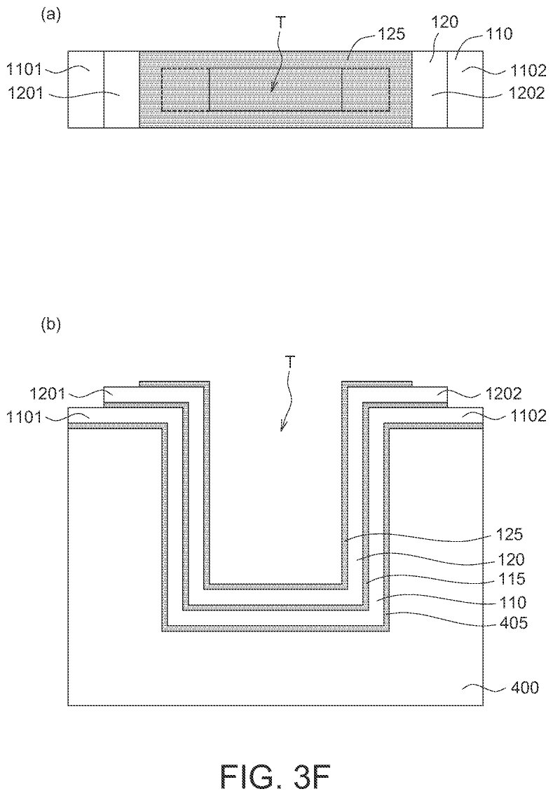

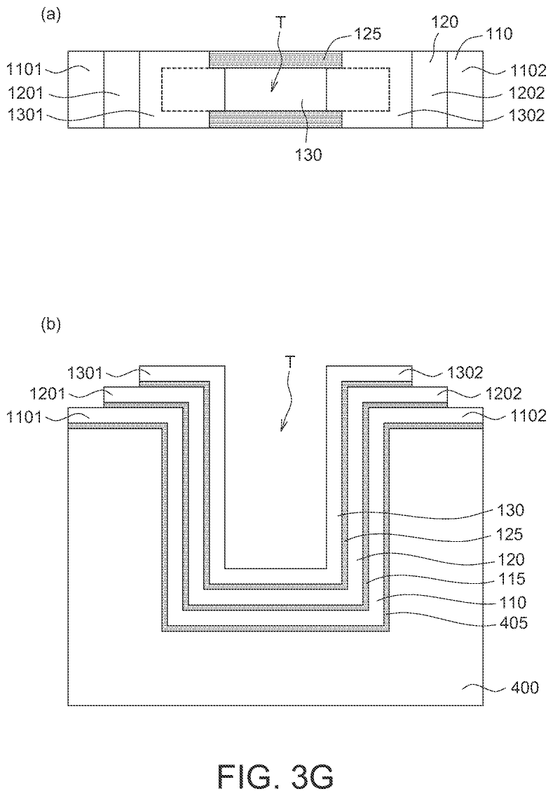

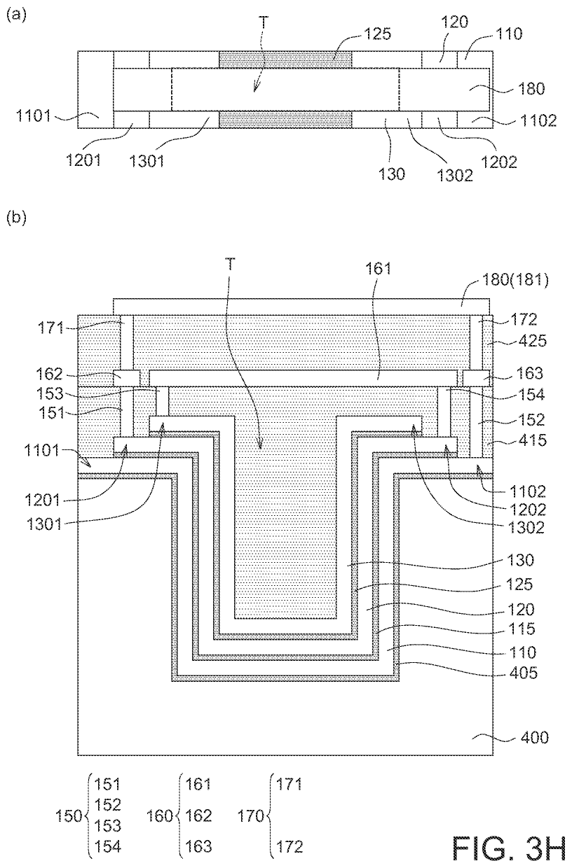

As to an electronic device with a three-loops inductor, FIGS. 3A-3H illustrate various stage of an exemplary method for manufacturing an electronic device comprising the inductor 100, wherein each part indicated with “a” shows a top view of the structure at the corresponding stage, and each part indicated with “b” shows a cross sectional view of the structure at the corresponding stage.

As shown in FIG. 3A, a substrate 400, such as but not limited to a silicon substrate is provided. The substrate 400 has a trench T. In the following drawings, the original area of the trench T will be shown in the top views by dotted lines.

As shown in FIG. 3B, before a first conductive layer 110 of the inductor 100 is conformally formed, a liner layer 405 can be conformally formed on the substrate 400. The liner layer 405 can be formed of oxide.

As shown in FIG. 3C, a first conductive layer 110 is conformally formed on the substrate 400. At least a portion of the first conductive layer 110 is formed in the trench T. The first conductive layer 110 has a first end portion 1101 and a second end portion 1102. The first conductive layer 110 can be formed of Cu, Al, or TiN.

As shown in FIG. 3D, before a second conductive layer 120 is conformally formed, a first dielectric layer 115 can be conformally formed on the first conductive layer 110. A sidewall of the first dielectric layer 115 can be coplanar with a sidewall of the second conductive layer 120 to be formed in the following step. The first dielectric layer 115 can be formed of a high-k material.

As shown in FIG. 3E, a second conductive layer 120 is conformally formed on the first dielectric layer 115. The second conductive layer 120 has a first end portion 1201 and a second end portion 1202 on the first end portion 1101 of the first conductive layer 110 and the second end portion 1102 of the first conductive layer 110, respectively. The second conductive layer 120 can be formed of Cu, Al, or TiN.

As shown in FIG. 3F, a second dielectric layer 1250 is conformally formed on the second conductive layer 120. A sidewall of the second dielectric layer 125 can be coplanar with a sidewall of a third conductive layer 130 to be formed in the following step. The second dielectric layer 125 can be formed of a high-k material.

As shown in FIG. 3G, a third conductive layer 130 is conformally formed on the second dielectric layer 125. The third conductive layer 130 as a first end portion 1301 and a second end portion 1302 on the first end portion 1201 of the second conductive layer 120 and the second end portion 1202 of the second conductive layer 120, respectively. The third conductive layer 130 can be formed of Cu, Al, or TiN.

Then, the first end portion 1201 of the second conductive layer 120 is electrically connected with the second end portion 1102 of the first conductive layer 110, and the first end portion 1301 of the third conductive layer 130 is electrically connected with the second end portion 1202 of the second conductive layer 120.

Specifically, as shown in FIG. 3H, four first conductive connectors 150, i.e., first conductive connectors 151-154, can be formed connected to the first end portion 1201 of the second conductive layer 120, connected to the second end portion 1102 of the first conductive layer 110, connected to the first end portion 1301 of the third conductive layer 130, and connected to the second end portion 1202 of the second conductive layer 120, respectively. A first overlying conductive layer 160 can be formed. The first overlying conductive layer 160 comprises a first overlying conductive portion 161, a second overlying conductive portion 162, and a third overlying conductive portion 163. The first overlying conductive portion 161 connects the first conductive connector 153 connected to the first end portion 1301 of the third conductive layer 130 and the first conductive connector 154 connected to the second end portion 1202 of the second conductive layer 120. The second overlying conductive portion 162 is connected to the first conductive connector 151 connected to the first end portion 1201 of the second conductive layer 120. The third overlying conductive portion 163 is connected to the first conductive connector 152 connected to the second end portion 1102 of the first conductive layer 110. Two second conductive connectors 170. i.e., second conductive connectors 171 and 172, can be formed connected to the second overlying conductive portion 162 and the third overlying conductive portion 163, respectively. A second overlying conductive layer 180 can be formed connecting the two second conductive connectors 171 and 172. More specifically, the second overlying conductive layer 180 has an overlying conductive portion 181 connecting the second conductive connectors 171 and 172.

In a similar manner, inductors having three loops, four loops, or even more loops can be manufactured.

In the disclosure, another kind of electronic device is provided. An electronic device of this kind comprises a substrate, an inductor, and a capacitor. The substrate has a trench. The inductor is disposed on the substrate. The inductor comprises a first conductive layer and a second conductive layer. The first conductive layer is conformally disposed on the substrate. At least a portion of the first conductive layer is disposed in the trench. The first conductive layer has a first end portion and a second end portion. The second conductive layer is conformally disposed on the first conductive layer. The second conductive layer has a first end portion and a second end portion on the first end portion of the first conductive layer and the second end portion of the first conductive layer, respectively. The first end portion of the second conductive layer is electrically connected with the second end portion of the first conductive layer. The capacitor is disposed in the trench or another trench of the substrate. The capacitor is electrically connected with the inductor.

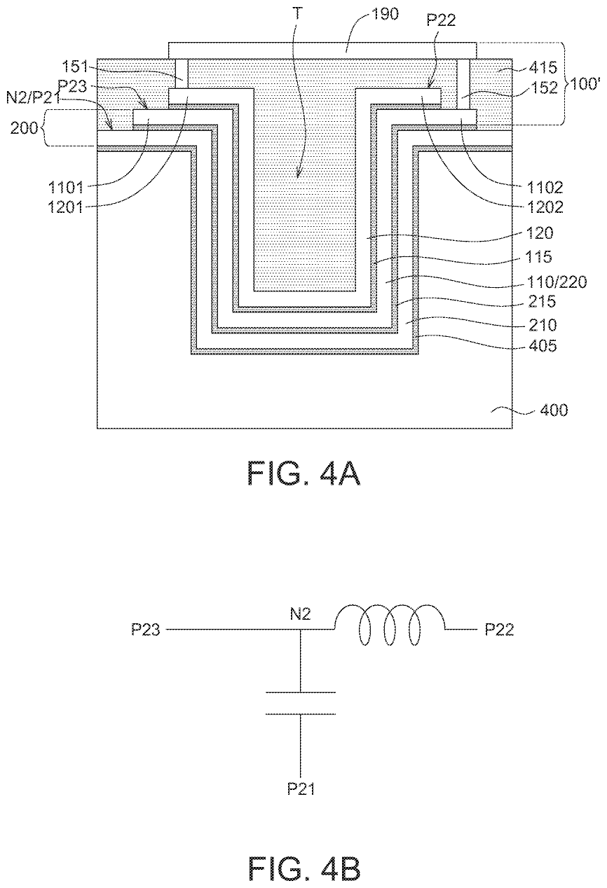

FIGS. 4A-4B illustrate another exemplary electronic device according to the disclosure. As shown in FIG. 4A, the electronic device comprises an inductor 100′ and a capacitor 200.

The inductor 100′ is a two-loops inductor, and comprises the first conductive layer 110, the first dielectric layer 115, and the second conductive layer 120. The first end portion 1201 of the second conductive layer 120 is electrically connected with the second end portion 1102 of the first conductive layer 110. Specifically, the electronic device can further comprise an overlying conductive layer 190 and conductive connectors 151-152. More specifically, the electronic device can comprise the interlayer dielectric layer 415 disposed on the substrate 400. The conductive connectors 151-152 penetrate through the interlayer dielectric layer 415. The overlying conductive layer 190 is disposed on the interlayer dielectric layer 415. The overlying conductive layer 190 is disposed over the second conductive layer 120. There are the conductive connectors 151-152, among which the conductive connector 151 is connected between the overlying conductive layer 190 and the first end portion 1201 of the second conductive layer 120, and the conductive connector 152 is connected between the overlying conductive layer 190 and the second end portion 1102 of the first conductive layer 110. Other details of the inductor 100′ are similar to those of the inductor 100, and will not be repeated again.

The capacitor 200 comprises a first capacitor conductive layer 210 and the first conductive layer 110. The first capacitor conductive layer 210 is conformally disposed under the first conductive layer 110. The first conductive layer 110 is separated from the first capacitor conductive layer 210 and used as a second capacitor conductive layer 220.

The capacitor 200 can further comprise a first capacitor dielectric layer 215 disposed between the first capacitor conductive layer 210 and the second capacitor conductive layer 220. However, it can be understood that the first capacitor conductive layer 210 and the second capacitor conductive layer 220 can be isolated by other structures, such as but not limited to an air gap, or a dielectric layer formed with an air gap.

The electronic device can be a bias tee with a circuit diagram as shown in FIG. 4B. The bias tee has three ports P21, P22, and P23. The port P21 is an RF port. The port P22 is a DC port. The port P23 is a RF and DC port. FIG. 4A shows the corresponding positions of the three ports in the structure and the corresponding position of a node N2.

As to a method for manufacturing such an electronic device, before the first conductive layer 110 is conformally formed on the substrate 400, a first capacitor conductive layer 210 can be conformally formed on the substrate 400, wherein at least a portion of the first capacitor conductive layer 210 is formed in the trench T. More specifically, the first capacitor conductive layer 210 and a first dielectric layer 215 can be firstly formed, and then the inductor 100′ can be manufactured with the method for manufacturing an electronic device as described above.

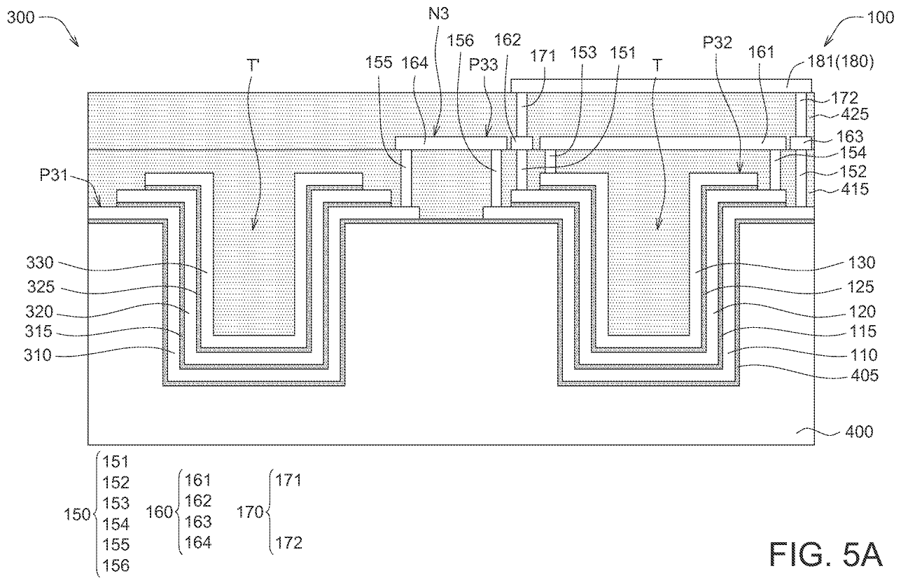

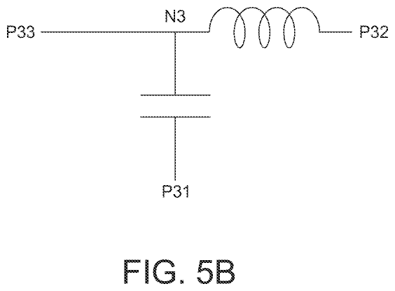

FIGS. 5A-5B illustrate still another exemplary electronic device according to the disclosure. The electronic device comprises the inductor 100 and a capacitor 300. The inductor 100 comprises the first conductive layer 110, the first dielectric layer 115, the second conductive layer 120, the second dielectric layer 125, and the third conductive layer 130 disposed sequentially. The first end portion 1201 of the second conductive layer 120 is electrically connected with the second end portion 1102 of the first conductive layer 11. The first end portion 1301 of the third conductive layer 130 is electrically connected with the second end portion 1202 of the second conductive layer 120. Specifically, the electronic device can further comprise the first overlying conductive layer 160, the second overlying conductive layer 180, and the conductive connectors 150 and 170. The first overlying conductive layer 160 is disposed over the second conductive layer 120. More specifically, in the presence of the third conductive layer 130, the first overlying conductive layer 160 is disposed over the third conductive layer 130. The second overlying conductive layer 180 is disposed over the first overlying conductive layer 160. There are the conductive connectors 150 and 170, among which the conductive connectors 171 and 151 are connected between the second overlying conductive layer 180 and the first end portion 1201 of the second conductive layer 120, the conductive connectors 172 and 152 are connected between the second overlying conductive layer 180 and the second end portion 1102 of the first conductive layer 110, the conductive connector 153 is connected between the first overlying conductive layer 160 and the first end portion 1301 of the third conductive layer 130, and the conductive connector 154 is connected between the first overlying conductive layer 160 and the second end portion 1202 of the second conductive layer 120. Other details of the inductor 100 will not be repeated again.

The capacitor 300 comprises a first capacitor conductive layer 310 and a second capacitor conductive layer 320. The first capacitor conductive layer 310 is conformally disposed on the substrate 400. At least a portion of the first capacitor conductive layer 310 is disposed in the another trench T. The second capacitor conductive layer 320 is conformally disposed on and separated from the first capacitor conductive layer 310. An end portion of the second capacitor conductive layer 320 is electrically connected with the first end portion 1101 of the first conductive layer 110.

In some embodiments, the capacitor 300 can further comprise a first capacitor dielectric layer 315 disposed between the first capacitor conductive layer 310 and the second capacitor conductive layer 320. However, it can be understood that the capacitor conductive layers can be isolated by other structures, such as but not limited to an air gap, or a dielectric layer formed with an air gap.

The capacitor 300 can further comprise a second capacitor dielectric layer 325 and a third capacitor conductive layer 330. The second capacitor dielectric layer 325 is conformally disposed on the second capacitor conductive layer 320. The third capacitor conductive layer 330 is conformally disposed on the second capacitor dielectric layer 325.

The conductive connectors 150 can further comprise conductive connectors) 155 and 156, and the first overlying conductive layer 160 can further comprise a fourth overlying conductive portion 164, for connecting the end portion of the second capacitor conductive layer 320 with the first end portion 1101 of the first conductive layer 110.

The electronic device can be a bias tee with a circuit diagram as shown in FIG. 5B. The bias tee has three ports P21, P22, and P23. The port P31 is an RF port. The port P32 is a DC port. The port P33 is a RF and DC port. FIG. 5A shows the corresponding positions of the three ports in the structure and the corresponding position of a node N3.

As to a method for manufacturing such an electronic device, while the first conductive layer 110 is conformally formed on the substrate 400, the first capacitor conductive layer 310 can be conformally formed on the substrate 400, wherein at least a portion of the first capacitor conductive layer 310 is formed in the another trench T′, and while the second conductive layer 120 is conformally formed on the first conductive layer 110, the second capacitor conductive layer 320 can be conformally formed on the first capacitor conductive layer 310. More specifically, after the formation of the liner layer 405, the first conductive layer 110 and the first capacitor conductive layer 310 can be formed in a same step, the first dielectric layer 115 and first capacitor dielectric layer 315 can be formed in a same step, the second conductive layer 120 and the second capacitor conductive layer 320 can be formed in a same step, the second dielectric layer 125 and the second capacitor dielectric layer 325 can be formed in a same step, the third conductive layer 130 and the third capacitor conductive layer 330 can be formed in a same step, all of the conductive connectors 150 (i.e., the conductive connectors 151-156) can be formed in a same step, the first overlying conductive layer 160 (comprising the first overlying conductive portion 161 to the fourth overlying conductive portion 164) can be formed, all of the conductive connectors 170 (i.e., the conductive connectors 171-172) can be formed in a same step, and the second overlying conductive layer 180 can be formed.

While deep trench capacitors are used as examples in both the embodiment of FIGS. 4A-4B and the embodiment of FIGS. 5A-5B, it can be understood that in the electronic device according to the disclosure, the inductor according to the disclosure can be used with other kinds of capacitors. Also, the electronic device according to the disclosure is not limited to a bias tee, and can be a filter or other kinds of electronic devices using inductors and capacitors. Compared with traditional electronic devices that require large capacitance and large inductance, the electronic device according to the disclosure can be significantly shrunk. In addition, the electronic device according to the disclosure can be integrated into a chip.

It is contemplated that a plurality of capacitors can be connected in series to increase the capacitance. A plurality of inductors, including or not including other types of inductors other than the deep trench inductors as described in the disclosure, can be connected in parallel to increase the inductance.

In the method for manufacturing an electronic device according to the disclosure, depending on the kind of the capacitor, some or all of the steps for manufacturing the capacitor can be conducted before, alternate with, combined with, or after some or all of the steps for manufacturing the inductor, without particular limitations.

In summary, an inductor that can be incorporated with a deep trench structure and various implementations related thereto are provided in the disclosure. An inductor according to the disclosure can be used together with any suitable electronic components, and particular a deep trench capacitor. The manufacturing process of the inductor is compatible with the manufacturing process of the deep trench capacitor, and is highly integrated with the CMOS process. An electronic device according to the disclosure has a smaller size, so that a tape-out area can be decreased and the cost can be reduced.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An electronic device, comprising:
a substrate having a trench; and
an inductor disposed on the substrate, the inductor comprising:
a first conductive layer conformally disposed on the substrate, at least a portion of the first conductive layer disposed in the trench, the first conductive layer having a first end portion and a second end portion; and
a second conductive layer conformally disposed on the first conductive layer, the second conductive layer having a first end portion and a second end portion on the first end portion of the first conductive layer and the second end portion of the first conductive layer, respectively;
wherein the first end portion of the second conductive layer is electrically connected with the second end portion of the first conductive layer.

2. The electronic device according to claim 1, wherein the first end portion of the first conductive layer and the first end portion of the second conductive layer form a stair structure, and the second end portion of the first conductive layer and the second end portion of the second conductive layer form a stair structure.

3. The electronic device according to claim 1, wherein each of the first conductive layer and the second conductive layer is formed of Cu, Al, or TiN.

4. The electronic device according to claim 1, further comprising:
a first dielectric layer conformally disposed on the first conductive layer, wherein the second conductive layer is conformally disposed on the first dielectric layer.

5. The electronic device according to claim 1, further comprising:
an overlying conductive layer disposed over the second conductive layer; and
conductive connectors connected between the overlying conductive layer and the first end portion of the second conductive layer and between the overlying conductive layer and the second end portion of the first conductive layer.

6. The electronic device according to claim 1, further comprising:
a third conductive layer conformally disposed on the second conductive layer, the third conductive layer having a first end portion and a second end portion on the first end portion of the second conductive layer and the second end portion of the second conductive layer, respectively;
wherein the first end portion of the third conductive layer is electrically connected with the second end portion of the second conductive layer.

7. The electronic device according to claim 6, wherein the first end portion of the third conductive layer together with the first end portion of the first conductive layer and the first end portion of the second conductive layer forms a stair structure, and the second end portion of the third conductive layer together with the second end portion of the first conductive layer and the second end portion of the second conductive layer forms a stair structure.

8. The electronic device according to claim 6, further comprising:
a second dielectric layer conformally disposed on the second conductive layer, wherein the third conductive layer is conformally disposed on the second dielectric layer.

9. The electronic device according to claim 6, further comprising:
a first overlying conductive layer disposed over the second conductive layer;
a second overlying conductive layer disposed over the first overlying conductive layer; and
conductive connectors connected between the second overlying conductive layer and the first end portion of the second conductive layer, between the second overlying conductive layer and the second end portion of the first conductive layer, between the first overlying conductive layer and the first end portion of the third conductive layer, and between the first overlying conductive layer and the second end portion of the second conductive layer.

10. The electronic device according to claim 6, further comprising:
a capacitor disposed in the trench or another trench of the substrate, the capacitor electrically connected with the inductor.

11. The electronic device according to claim 10, wherein the capacitor comprises:
a first capacitor conductive layer conformally disposed under the first conductive layer; and
the first conductive layer separated from the first capacitor conductive layer and used as a second capacitor conductive layer.

12. The electronic device according to claim 10, wherein the capacitor comprises:
a first capacitor conductive layer conformally disposed on the substrate, at least a portion of the first capacitor conductive layer disposed in the another trench; and
a second capacitor conductive layer conformally disposed on and separated from the first capacitor conductive layer;
wherein an end portion of the second capacitor conductive layer is electrically connected with the first end portion of the first conductive layer.

13. A method for manufacturing an electronic device, comprising:
providing a substrate, the substrate having a trench;
conformally forming a first conductive layer on the substrate, at least a portion of the first conductive layer formed in the trench, the first conductive layer having a first end portion and a second end portion;
conformally forming a second conductive layer on the first conductive layer, the second conductive layer having a first end portion and a second end portion on the first end portion of the first conductive layer and the second end portion of the first conductive layer, respectively; and
electrically connecting the first end portion of the second conductive layer and the second end portion of the first conductive layer.

14. The method according to claim 13, further comprising:
before conformally forming the first conductive layer, conformally forming a liner layer on the substrate, at least a portion of the liner layer formed in the trench.

15. The method according to claim 13, further comprising:
before conformally forming the second conductive layer, conformally forming a first dielectric layer on the first conductive layer.

16. The method according to claim 13, wherein electrically connecting the first end portion of the second conductive layer and the second end portion of the first conductive layer comprises:
forming two conductive connectors connected to the first end portion of the second conductive layer and connected to the second end portion of the first conductive layer, respectively; and
forming an overlying conductive portion connecting the two conductive connectors.

17. The method according to claim 13, further comprising:
conformally forming a second dielectric layer on the second conductive layer;
conformally forming a third conductive layer on the second dielectric layer, the third conductive layer having a first end portion and a second end portion on the first end portion of the second conductive layer and the second end portion of the second conductive layer, respectively; and
electrically connecting the first end portion of the third conductive layer and the second end portion of the second conductive layer.

18. The method according to claim 17, wherein electrically connecting the first end portion of the second conductive layer and the second end portion of the first conductive layer and electrically connecting the first end portion of the third conductive layer and the second end portion of the second conductive layer comprise:
forming four first conductive connectors connected to the first end portion of the second conductive layer, connected to the second end portion of the first conductive layer, connected to the first end portion of the third conductive layer, and connected to the second end portion of the second conductive layer, respectively;
forming a first overlying conductive layer comprising a first overlying conductive portion, a second overlying conductive portion, and a third overlying conductive portion, the first overlying conductive portion connecting the first conductive connector connected to the first end portion of the third conductive layer and the first conductive connector connected to the second end portion of the second conductive layer, the second overlying conductive portion connected to the first conductive connector connected to the first end portion of the second conductive layer, the third overlying conductive portion connected to the first conductive connector connected to the second end portion of the first conductive layer;
forming two second conductive connectors connected to the second overlying conductive portion and the third overlying conductive portion, respectively; and
forming a second overlying conductive layer connecting the two second conductive connectors.

19. The method according to claim 13, further comprising:
before conformally forming the first conductive layer on the substrate, conformally forming a first capacitor conductive layer on the substrate, at least a portion of the first capacitor conductive layer formed in the trench.

20. The method according to claim 13, wherein the substrate has another trench, and the method further comprises:
while conformally forming the first conductive layer on the substrate, conformally forming a first capacitor conductive layer on the substrate, at least a portion of the first capacitor conductive layer formed in the another trench; and
while conformally forming the second conductive layer on the first conductive layer, conformally forming a second capacitor conductive layer on the first capacitor conductive layer.
